(19) United States
(12) Patent Application Publication
(10) Pub. No.: US 2004/0041599 A1
(43) Pub. Date: Mar. 4, 2004

(54) Non-linear reference waveform generators for data conversion and other applications

(76) Inventor: Charles Douglas Murphy, Evanston, IL (US)

Correspondence Address: Charles D. Murphy, 601 Linden Place #210, Evanston, IL, 60202, US

(21) Appl. No.: 10/228,372

(22) Filed: Aug. 27, 2002

(51) Int. Cl. H03B 1/00

(52) U.S. Cl. 327/129

(57) ABSTRACT

A machine for generating piece-wise non-linear reference waveforms at low cost, particularly in integrated circuit technologies. The reference waveform can be a distorted sinusoidal waveform such as a truncated sinusoid. Provided that local distortion is low enough in some waveform segments, for instance, in the transitions between saturation levels, parts of the waveform can be used as non-linear reference segments in data converters based on comparison of inputs. The distorted sinusoidal waveform can also be filtered to reduce distortion. In the preferred embodiment of the invention, suitable sinusoids with high or low distortion can be generated using an op-amp configured with a Wien Bridge providing positive feedback and a resistor bridge providing negative feedback. The invention differs from prior art Wien Bridge oscillators in having negative feedback gain that forces the op-amp output into saturation. One filter stage is provided by the positive feedback network itself. Additional filtering can allow further distortion reduction. The specification suggests a cascade of servo-grounded Wien Bridge stages as a simple and efficient approach to the filtering. The invention can be fabricated using a small number of parts which are easy to fabricate with existing integrated circuit technologies such as CMOS, so that low-cost, low-power implementations can be included in mixed-signal chips as parts of A/D converters, D/A converters, or calibration signal generators. The invention is also amenable to massively parallel and shared implementations, for instance, on a CMOS image sensor array chip or on a image display device.

### CROSS-REFERENCE TO RELATED APPLICATIONS

The invention is related to ANALOG-TO-DIGITAL CONVERSION WITH PIECE-WISE NON-LINEAR REFERENCE WAVEFORMS submitted as a separate application by the US PTO by the applicant of the present invention and having filing date Jun. 24, 2002 and filing number 10/179937.

### STATEMENT REGARDING FEDERALLY SPONSORED RESEARCH OR DEVELOPMENT

Not applicable

### REFERENCE TO A MICROFICHE APPENDIX

Not applicable

### BACKGROUND—FIELD OF INVENTION

The invention relates to non-linear reference signal generation, particularly to the generation of sinusoids with overall low distortion and to the generation of high-distortion sinusoids that include low-distortion waveform segments, to use of such signals as reference waveforms in data converters, and to low-cost generator implementations in integrated circuit technologies.

### BACKGROUND—DESCRIPTION OF PRIOR ART

Prior art single-slope, dual-slope, and multi-slope analog-to-digital (A/D) converters attempt to provide a linear mapping between a partitioned range of allowed analog input values and an ordered set of allowed digital output values by measuring the elapsed time required for a linearly time-varying difference between analog signals to reach zero. The elapsed time is recorded on receipt of a signal from a comparator. Usually, the comparator has one input which is held constant during a single measurement cycle and one input which is a linear ramp segment during the measurement cycle.

Linear ramp segments can be generated by charging or discharging a capacitor with a constant current. Viewed over multiple measurement cycles, a time-varying waveform which includes linear ramp segments is non-linear, since the capacitor may be periodically initialized to a starting charge state to avoid current source saturation. Even over the course of a single ramp segment, linearity is imperfect due to dielectric absorption. Dielectric absorption results in a ramp segment which is only asymptotically linear.

For the purposes of the present invention, a waveform having segments which are treated as being ideal linear segments is a “linear segment waveform”. Distortion due to dielectric absorption may be sufficiently small to be ignored, especially in the context of low-precision data converters or low-speed data converters. On the other hand, a waveform having non-linear segments that are treated as non-linear segments rather than as ideal linear segments is a “non-linear segment waveform”. Unfortunately, when distortion due to dielectric absorption is non-negligible, as is the case in high-precision or high-speed data converters, there are not any effective, low-cost methods for estimating or otherwise correcting the deviation from ideal linearity.

The applicant proposed piece-wise nonlinear reference waveforms—in the present application referred to as “non-linear segment waveforms”—as alternatives to piece-wise linear waveforms for A/D converters based on comparison and elapsed time recording, in the related application ANALOG-TO-DIGITAL CONVERSION WITH PIECE-WISE NON-LINEAR REFERENCE WAVEFORMS. By tolerating deviations from a linear ramp segment otherwise leading directly to a linear conversion mapping, it is possible to implement faster, lower-cost, and higher-precision A/D converters based on waveform comparison. Two requirements, however, are the ability to generate accurate piece-wise nonlinear reference waveforms and the ability to transform a given nonlinear mapping of input levels to recorded times into a desired linear mapping.

In the related application, the applicant proposed sinusoids as particularly useful piece-wise nonlinear reference waveforms. The generation of sinusoids is a mature and well-established art, with numerous techniques available in the bodies of work on audio signal processing and communications.

Sinusoids are often characterized by harmonic distortion, which is quoted on sinusoid generator data sheets as total harmonic distortion (THD) in units of fractions of percents. The distortion present in a generated sinusoid is usually measured by filtering to separate the desired fundamental harmonic from non-fundamental harmonics. One filtering approach is to apply the generated sinusoid to a notch filter at the fundamental frequency, and to measure the amplitude of the resulting residual distortion signal relative to the unfiltered sinusoid. Another filtering approach is to compute a Fourier transform of the generated sinusoid and then to measure the relative amplitudes of the various harmonic peaks. This approach can be implemented using a frequency-swept analog bandpass filter, or in the digital domain using an A/D converter and a discrete Fourier transform. Of course, the digital version of the latter approach requires an A/D converter of suitable linearity in order to provide a meaningful distortion measurement.

As an example of distortion measurement claims, suppose that a generated sinusoid has an amplitude of 1 V, and the waveform resulting from notch filtering at the fundamental frequency has an amplitude of 0.1 mV. The THD is declared to be 0.01 percent. A 0.01 percent maximum deviation corresponds to slightly more than 13 bits of linear precision. It is important to note, however, that neither time-domain nor frequency-domain filtering used to produce such a distortion measurement takes into account localization of the distortion in the waveform.

In prior art literature, Linear Technology Application Note 43 describes sinusoidal oscillators that have distortion of 0.0003 percent, or slightly more than 18 bits of precision, using discrete parts. Krohn-Hite Corporation offers an “Ultra-Low Distortion Oscillator”, model 4402B, which has a distortion between 1 Hz and 10 kHz of 0.0005 percent (slightly more than 17 bits of precision), though the device weights 2.3 kilograms and has a volume of 4400 cubic centimeters. The AG15C Programmable Low Distortion Oscillator from the Japanese company Shibasoku, also a large instrument in a rack-mountable chassis, boasts harmonic distortion of under 0.0001 percent (slightly less than 20 bits of precision).

The low-distortion sinusoidal generators in Linear Technology Application Note 43 are based on the Wien Bridge oscillator, which is also discussed on pages 297-302 of THE ART OF ELECTRONICS by Winfield Hill and Paul Horowitz, and—of some historical interest—in the 1939 master's thesis of Hewlett-Packard co-founder Walter R. Hewlett.

A Wien Bridge oscillator comprises an op-amp with positive feedback through a simple RC network—the Wien Bridge—and negative feedback through a resistor network containing a variable resistance element. The RC network in the positive feedback path to the non-inverting op-amp input forms a bandpass filter at a desired oscillation frequency. The variable resistor network in the negative feedback path dynamically adjusts the negative feedback gain about an ideal operation point, which is the equilibrium gain. If the negative feedback gain is consistently less than the equilibrium gain, the oscillations of the op-amp output will die out. If the negative feedback gain is consistently greater than the equilibrium gain, the oscillations will increase in amplitude until the op-amp output saturates. The negative feedback gain modulation ideally keeps the actual negative feedback gain at the equilibrium gain, so that oscillation is maintained with constant maximum and minimum amplitudes.

The Wien Bridge oscillator is a promising candidate for generating sinusoidal reference waveforms on account of its small component count. However, it seems unlikely that there is an uncomplicated way to implement the negative feedback gain modulation in, say, a standard CMOS manufacturing process. Integrated circuits dedicated to mimicking the effects of the #327 Lamp in Linear Technology Application Note 43 figure 39 and in figure 5.42 on page 296 of THE ART OF ELECTRONICS may require a substantial number of additional active and passive components, if not some additional processing steps geared toward fabrication of unusual components.

### SUMMARY

The present invention enables low-cost generation of piece-wise nonlinear reference waveforms, also known as non-linear segment waveforms, particularly of waveforms which exhibit some accurate sinusoidal reference segments but which also exhibit non-sinusoidal waveform segments and which are consequently not themselves low-distortion sinusoids. These non-linear segment waveforms can be used directly as reference waveforms or can be filtered to provide more-accurate sinusoidal reference waveforms.

### OBJECTS AND OBJECTIVES

There are several objects and objectives of the present invention.

It is an object of the present invention to provide means for generating piece-wise nonlinear reference waveforms having some desirable, accurate waveform segments and having some undesirable, inaccurate waveform segments. The desirable, accurate waveform segments are non-linear segments processed as such, while the undesirable, inaccurate waveform segments may be present but not used.

It is another object of the present invention to provide means for generating high-distortion sinusoids which are nonetheless well-suited to being reference waveforms in data converters, such as A/D converters based on waveform segment comparison and elapsed time count recording, or such as D/A converters based on tracked-and-held or sampled-and-held analog values.

It is still another object of the present invention to provide means for generating relatively high-distortion sinusoids which are subsequently filtered to produce relatively low-distortion sinusoids. The low-distortion sinusoids can be used for data conversion or as reference signals in such applications as instrument calibration or waveform generation.

It is a further object of the present invention to provide a class of self-starting, self-sustaining oscillators which use a small number of components of reasonably low cost. The components, and hence the oscillators, can be co-fabricated with other analog and digital circuits in standard integrated circuit technologies such as CMOS.

It is yet another object of the present invention to provide an oscillator for data converters which can be implemented massively in parallel or as a shared component in a massively parallel bank of data converters. Massively parallel data converters may be very useful in digital image acquisition systems, such as in imaging arrays of CMOS image sensors, or in image display devices.

It is an object of the present invention to enable low-power, low-precision data conversion and also to enable low-power, high-precision data conversion.

Further objects and advantages of the invention will become apparent from a consideration of the ensuing description.

### DRAWING FIGURES

In the drawings, closely related figures have the same number but different alphabetic suffixes.

FIG. 1A shows a block diagram of a preferred embodiment of the present invention.

FIG. 1B shows a block diagram of an alternative embodiment of the present invention which reduces distortion due to common-mode gain.

FIG. 1C shows a block diagram of an alternative embodiment of the present invention which uses a simple filter circuit to produce sinusoidal waveform with improved accuracy relative than those available in FIGS. 1A and 1B.

### REFERENCE NUMERALS IN DRAWINGS

10 a first op-amp

12 a first inverting op-amp input

14 a first non-inverting op-amp input

16 a first op-amp output

18 a first resistor

20 a first capacitor

22 a second capacitor

24 a second resistor

26 a third resistor

28 a fourth resistor

30 a second op-amp

32 a second inverting op-amp input

34 a second non-inverting op-amp input

36 a second op-amp output

38 a fifth resistor

40 a third capacitor

42 a sixth resistor

44 a fourth capacitor

46 a third op-amp

48 a third inverting op-amp input

50 a third non-inverting op-amp input

52 a third op-amp output

### DESCRIPTION—THE PREFERRED EMBODIMENT OF THE INVENTION

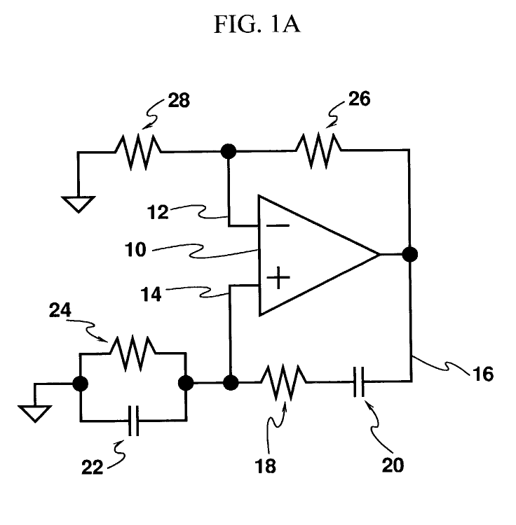

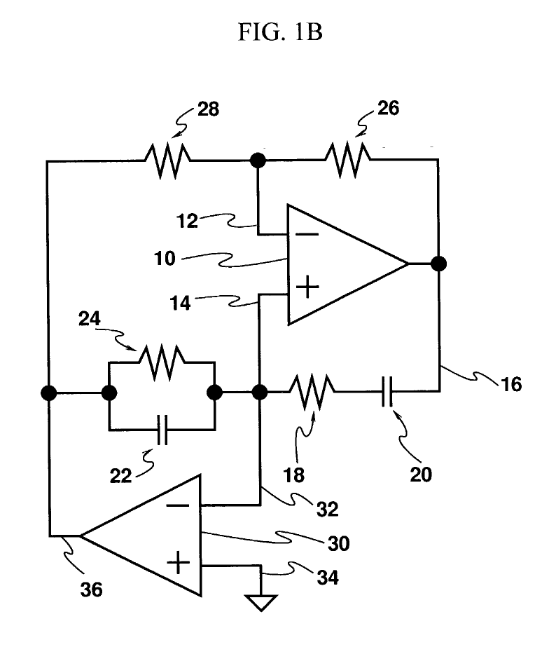

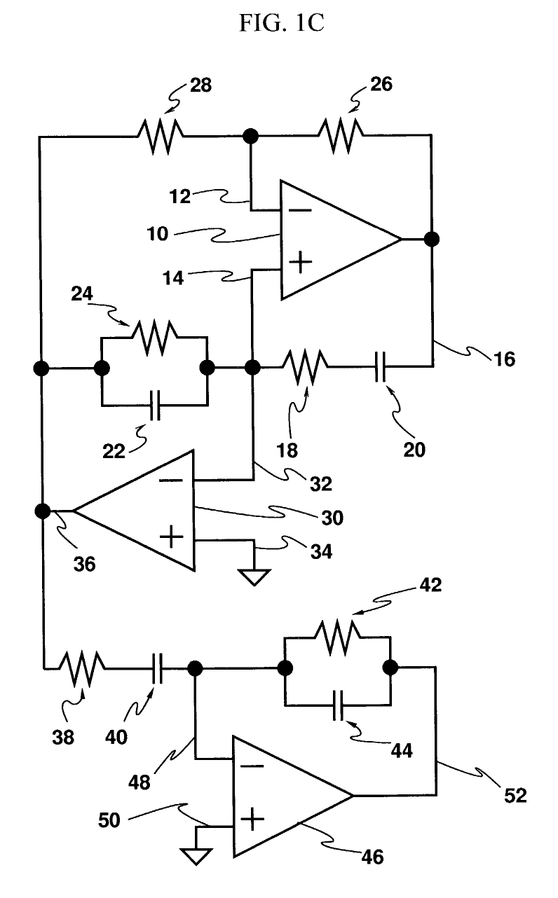

The preferred embodiment of the invention is shown in the form of a block diagram in FIG. 1A. A first op-amp 10 has a first inverting op-amp input 12, a first non-inverting op-amp input 14, and a first op-amp output 16. First op-amp output 16 is connected to first non-inverting op-amp input 14 via a two-leg R-C network known as a Wien bridge. The first leg has a first resistor 18 and a first capacitor 20 in series, while the second leg, which is connected to a reference voltage depicted as ground, has a second resistor 24 in parallel with a second capacitor 22. Given non-zero resistance and capacitance values, the Wien bridge acts as a bandpass filter to which the op-amp output is applied. A common choice in building an oscillator based on the Wien bridge is for first resistor 18 and second resistor 24 to have a single common resistance value R and for first capacitor 20 and second capacitor 22 to have a single common capacitance value C. The resonant frequency at which the signal fed back to first non-inverting op-amp input 14 has the maximum amplitude is then ½πRC.

First op-amp output 16 is also connected to first inverting op-amp input 12 by way of a resistor network formed by third resistor 26 and fourth resistor 28. The values of the two resistors define a negative feedback gain. With single resistance and capacitance values for the Wien bridge network that provides positive feedback of the output, a fixed negative feedback gain of less than three is insufficient to sustain an oscillation in the value of first op-amp output 16, while a fixed negative feedback gain of more than three causes an oscillation in the value of first op-amp output 16 to increase in amplitude until the negative feedback gain is limited by op-amp saturation. The transition value defining the boundary between insufficient and saturation-inducing gain is the equilibrium gain.

In Wien bridge oscillators designed to produce low-distortion sinusoids, either third resistor 26 or fourth resistor 28 is in fact a variable resistance. In order to have an oscillation that neither dies away nor saturates, the negative feedback gain is modulated in a small region about the equilibrium feedback gain. For instance, in figure 5.42A on page 297 of THE ART OF ELECTRONICS, a basic Wien bridge oscillator is shown in which fourth resistor 28 is replaced by a #327 lamp, while in figure 5.42B fourth resistor 28 is replaced by two resistors, two capacitors, a JFET, a diode, and a Zener diode.

In the preferred embodiment of the invention in FIG. 1A, the values of third resistor 26 and fourth resistor 28 are constant. The constant values should be such that the negative feedback gain is greater than the equilibrium gain. This forces the oscillation of first op-amp output 16 into the saturation region of first op-amp 10, resulting in a distorted sinusoid. However, the transitions of op-amp output 16 between the positive and negative saturation values may be relatively undistorted sinusoidal waveform segments, which can be used in an A/D converter based on comparing the segments to analog inputs and recording digital counts at crossover times or in a D/A converter.

There are several advantages to generating a distorted sinusoid in lieu of a low-distortion sinusoid. There is no need for analog circuitry to implement feedback gain modulation. While the use of a temperature-varying resistor such as the filament of a #327 lamp or the use of gain control based on a JFET and diodes are possible with discrete components, it may not be the case that similar performance vis-à-vis local waveform segment distortion can be obtained in integrated circuit realizations, such as in CMOS technologies, without a fairly large amount of circuitry beyond the op-amp and the few passive components shown in FIG. 1A.

Another advantage is that with forced saturation, the oscillator is guaranteed to both begin and continue oscillation. No start-up control circuitry is required. With proper selection of resistor and capacitor values, oscillation can be ensured even in the presence of fixed component variations resulting from manufacturing or in the presence of slow time variations resulting from temperature changes or component aging.

The main disadvantage of using a truncated sinusoid for compare-and-record A/D conversion is that there is time in each oscillation cycle occupied by non-useful waveform segments which are either saturated waveform segments or sinusoidal waveform segments with too much distortion. This may limit the conversion speed or the conversion precision.

For instance, if a 200 MHz digital counter is available, and 20 bit A/D conversion is desired, the time required for one conversion is approximately 5.242 milliseconds. A maximum of slightly more than 190 conversion cycles are possible in one second. If the non-useful saturated waveform segments occupy 20 percent of each waveform cycle, then the conversion cycle time increases to a minimum of 6.291 milliseconds—5.242 milliseconds for full counting through all 2²⁰ possible count values, and an additional 1.048 milliseconds occupied by non-useful waveform segments. With the longer conversion cycle time, only slightly more than 158 conversion cycles are possible in one second. The dead time when the waveform's non-useful segments occur is not entirely wasted, since it is possible to perform other processing steps such as re-mapping or other digital correction of measured count values during that time.

Not shown in FIG. 1A, but potentially necessary for proper functioning of embodiments of the invention in data converters, are circuitry to synchronize digital counter values to the beginning or ending of useful nonlinear reference waveform segments and means for accommodating errors in the effective amplitude of the sinusoid represented by the sinusoidal segments. The related application ANALOG-TO-DIGITAL CONVERSION WITH PIECE-WISE NON-LINEAR REFERENCE WAVEFORMS includes some discussion of existing techniques for synchronization—which might include phase-locked loops, modified peak detectors, or even a simple comparator circuit—and amplitude error compensation, along with a discussion on mapping transformations of measured counts.

Description—Alternative Embodiments of the Invention

It is pointed out in Linear Technology Application Note 43 that a great deal of distortion in the low-distortion sinusoids produced by ordinary Wien bridge oscillators results from common mode gain of the driving op-amp. This distortion can be largely eliminated by using additional op-amp circuitry to remove the common mode signal. FIG. 1B shows an alternative embodiment of the invention with a similar approach. The basic circuits in FIG. 1B are identical to those in FIG. 1A, with the exception of the reference ground to which fourth resistor 28, second resistor 24, and second capacitor 22 were connected being replaced by a connection to a second op-amp output 36 of a second op-amp 34.

In FIG. 1B, second non-inverting op-amp input 34 is connected to the reference ground, and second inverting op-amp input 32 is connected to the same node as first non-inverting op-amp input 14. Second op-amp 34 thus acts to pin the voltage at the node of first non-inverting op-amp input 14 to ground, making that node a virtual ground. Second op-amp 34 servo-grounds the node by accommodating a swing in the value of first op-amp output 16 with a swing of opposite polarity in second op-amp output 36.

The oscillator of FIG. 1B can be used in much the same manner as that of FIG. 1A, with first op-amp output 16 being a distorted sinusoidal waveform. The quality of the desired, accurate waveform segments which occur when first op-amp output 16 transitions between positive and negative saturation depend a great deal on how close the negative feedback gain defined by third resistor 26 and fourth resistor 28 is to the equilibrium gain defined the Wien bridge in the positive feedback loop. It is clear that with a limited set of allowed resistance values and with capacitance and resistance values that may be in error due to manufacturing variations, temperature, or aging, it may be either desirable or even necessary to select a negative feedback gain which is not particularly close the equilibrium gain.

In an alternative embodiment of the invention, a node voltage value other than that of first op-amp output 16 can be used as the source of an oscillatory waveform used in A/D conversion. Of particular interest is the value of second op-amp output 36 in FIG. 1B. First op-amp output 16 drives the Wien bridge circuit. At the node connected to first non-inverting op-amp input 14, the voltage always has a magnitude less than that of first op-amp output 16, which means that the voltage at this node never saturates. In FIG. 1B, second op-amp output 36 oscillates with polarity opposite to that of first op-amp output 16, but with a smaller magnitude. Thus, if first op-amp 10 and second op-amp 30 have the same saturation levels, second op-amp output 36 never saturates!

The waveform at first non-inverting op-amp input 14 in FIG. 1A and the waveform of second op-amp output 36 in FIG. 1B are both more-accurate sinusoids than the waveform of first op-amp output 16 in the appropriate circuit, albeit with reduced amplitude. The reason for the improved waveform shape is that the Wien bridge acts to suppress some of the high-magnitude harmonics that are present in the saturated (or near-saturated) waveform of first op-amp output 16.

FIG. 1C shows an alternative embodiment of the invention in which the signal the output of a servo-grounding op-amp is further filtered to provide a sinusoid of improved waveform shape. Second op-amp output 36 is connected to a fifth resistor 38 in series with a fourth capacitor 40. Third capacitor 40 is connected to a third inverting op-amp input 48 belonging to a third op-amp 46 and to a parallel circuit of a fourth capacitor 44 and a sixth resistor 42. The parallel circuit is connected to third op-amp output 52, and third non-inverting op-amp input 50 of third op-amp 46 is connected to ground.

Fifth resistor 38, third capacitor 40, sixth resistor 42, and fourth capacitor 44 form a Wien bridge. Natural choices for the bridge component values are the same resistance R and capacitance C selected for the Wien bridge providing positive feedback to first op-amp 10. The two Wien bridges then have the same resonant frequency.

The circuit of FIG. 1C includes a first waveform at first op-amp output 16 which is a distorted sinusoid. The distortion results from first op-amp 10 being forced into saturation by dint of a negative feedback gain greater than the equilibrium gain defined by the positive feedback network of the first Wien bridge. Second op-amp 30 acts to servo-ground first non-inverting op-amp input 14, and simultaneously—with no additional components—provides a waveform at second op-amp output 36 which is a filtered version of the distorted sinusoid of first op-amp output 16. In turn, third op-amp 46 servo-grounds the center of a second Wien bridge driven by second op-amp output 36. The waveform at third op-amp output 52 is a twice-filtered version of first op-amp output 16.

It is easy to add further filtering stages to the circuit of FIG. 1C. The advantages of the cascade approach depicted in the figure are that the components of each stage are small in number and relatively easy to implement in the form of an integrated circuit. The filter stages can have a common structure, and may use a single op-amp building block, since each stage is required to receive one driving signal across a Wien bridge and to provide at most one driving signal to a Wien bridge. It may be necessary, of course, to include some form of amplification and perhaps a driving buffer when a waveform is ultimately passed to other circuits. The additional amplification and buffer circuits are not shown in the figures, but their potential need is noted here.

While negative feedback gain which is greater than the positive feedback gain ensures oscillation, some care should be taken in selecting the gain values. If the negative feedback gain is too much greater than the positive feedback gain, first op-amp output 16 is saturated during most of any given oscillation cycle, and the non-saturated transition waveform segments may be slew-rate limited. The results are that the waveform may be undesirably distorted over the entire oscillation cycle and—worse—that the fundamental oscillation frequency is lower than the desired fundamental oscillation frequency. Filtering of such a highly distorted waveform using a small number additional bandpass stages at the resonant frequency of the Wien bridge providing the positive feedback is unlikely to result in a clean sinusoid.

One alternative is to filter the highly distorted waveform at its fundamental frequency rather than at the resonant frequency of the Wien bridge providing the positive feedback. However, a better alternative is to design an embodiment of the invention with an op-amp and relative positive and negative feedback gains that result in a clipped sinusoid which has a fundamental frequency at the resonant frequency of the positive feedback network and which has a low clipping duty cycle. Since the waveform is already a reasonable approximation of a sinusoid, a small number of additional filtering stages can result in a very low distortion sinusoid. Note also that a cascade of Wien bridge circuits results in a sinusoid with reduced distortion and with reduced amplitude. Gain circuitry may be required to restore a desired amplitude between or after filtering stages.

There are numerous other oscillator circuits which have been designed to provide sinusoidal signals. Filtering of square or triangle waveforms can yield sinusoidal signals, albeit with high-order filtering required for accurate sinusoids. There are also state-variable oscillators, phase sequence filters, quartz crystal oscillators, resonant cavity oscillators and various incarnations of Colpitts, Hartley, Pierce, Wien bridge, or other oscillators made with combinations of active and passive components. Many of these may be candidates for alternative embodiments of the present invention. Different types of oscillators perform more or less well in different oscillation frequency ranges. Additionally, there may be stabilization and compensation circuits which eliminate various unwanted effects and which might prove useful in alternative embodiments.

Discussion—Integrated Circuit Implementations

The invention is of greatest value when implemented in an integrated circuit. In particular, the invention is intended to enable data converters (analog-to-digital converters or digital-to-analog converters) which are reliable, simple to design, compact in structure, and power-efficient. To this end, the embodiments described above which use Wien bridge circuits seem quite promising, especially as they can be incorporated into mixed-signal chips using pre-existing integrated circuit processing steps and well-understood components.

One difficulty in mixed-signal IC design is that certain types and values of components are difficult to manufacture accurately. For instance, resistors are often avoided in IC implementations because they require a great deal of space. Problems of size are exacerbated when one requires well-matched components, which leads to the complaint that analog circuits do not scale with decreasing process size as do digital circuits.

An alternative embodiment of the invention, which is useful regardless of whether or not greater-than-minimum component sizes are required in a particular IC manufacturing process, is in massively parallel shared data conversion. For instance, in A/D conversion, a sinusoid of low or high distortion can be used as a reference waveform in multiple converters which operate simultaneously. This allows relatively low-frequency waveforms to be used for high-speed conversion.

As an example, a single oscillator embodying the present invention can be included on an integrated circuit chip which contains a large array of CMOS image sensors. An array of 2000 by 2000 pixels or picture elements may contain 4 million such sensors, or, in the case of new imaging chips available from Foveon, 3 sensors per pixel for a total of 12 million such sensors. Each sensor output must be converted to a digital number value, with sets of concurrently-acquired digital number values defining still images, and sequences of images making up video. With a purely serial A/D converter, 4 million sensors would require 4 million successive conversion operations for image acquisition. A relatively fast AID converter operating at 4 megasamples per second (MSPS) could convert all the conversions in 1 second. Two such converters would complete the task in 0.5 seconds, four such converters in 0.25 seconds, and so on.

With the present invention, slow, parallel, low-cost converters are possible. With an oscillation frequency of 2000 Hz, which is quite low, it would only be possible to complete up to 4000 successive conversion operations per second. However, with 1000 parallel AID converters each comprising a comparator, but sharing a counter and a reference waveform (or buffered replicas of a single generated waveform), it is possible to complete 4 million conversions in one second. Switching and routing circuitry required to move sensor outputs in few-converter-many-sensor systems would be reduced, as would the power consumption associated with converters having short conversion cycle times. Another advantage of the present invention over the prior art is that with a sufficiently fast counter and with sufficiently accurate waveform segments, it is possible to implement high-precision parallel converters, which can extend the dynamic range of integrated circuit imaging arrays.

Another interesting application of the present invention is on-chip testing. The sinusoidal waveform segments can be used to calibrate an A/D converter or a D/A converter. For instance, in self-adaptive silicon (SAS) technologies, a small number of floating-gate transistors can have charge selectively added or removed in order to change the transistor properties. The properties can be manipulated to tune a data converter after manufacture. The present invention can be used to provide a reference signal to be used in the tuning process, and may be implemented either as a separate reference-generation system or on the same chip as the adaptive transistors.

SAS, in turn, can be used to create variable-frequency oscillators according to the present invention. In particular, as SAS promises low-cost variable capacitors and the present invention can be implemented with a relatively small number of capacitors, SAS technology may be used to adjust the resonant frequency of the Wien bridge circuits in FIGS. 1A, 1B, and 1C. The invention can be used for testing and calibration of other devices as well. For instance, it can be used for high-fidelity audio signal generation in order to test speakers, microphones, or amplifiers.

Discussion—Linearity and Data Converters

A goal of data converter design is to provide a linear mapping between contiguous sets of analog input (or output, in the case of D/A converters) values and an ordered set of digital output (or input) values. Typically the range of allowed analog signal levels has a maximum value and a minimum value, while the set of digital signal values contains some exponential number (e.g. 2ⁿ, give or take a duplicate code word, for n bits of precision) of allowed representations. A linear mapping is achieved when each analog value bin has the same size, with the possible exception of the bins corresponding to the largest and the smallest digital signal values. Then, digital numbers differing by a particular digital value reflect analog values differing by the digital value multiple of the common bin size. In such a case, mathematical operations performed digitally are good approximations to the same mathematical operations performed on the analog values, subject, of course, to the effects of quantization.

A drawback of many high-precision data converters is that they in fact implement a nonlinear mapping between analog input values and digital output values. Two parameters that appear on data converter data sheets and that indicate to some extent the nonlinearity of a mapping are the integral nonlinearity (INL) and the differential nonlinearity (DNL). These are usually quoted in terms of least significant bit (LSB) intervals.

INL measures the maximum error range between an ideal linear transfer function and the actual transfer function of a converter representative of a particular design and manufacturing process. INL can be measured in terms of least-significant bit (LSB) intervals. For instance, a 24-bit A/D converter may have a listed INL of 256 LSB. This means that a digital output may be in error by as many as 8 bits. In other words, the 24-bit A/D converter in question is only linear to 16 bits of precision! DNL measures the largest deviation in bin size from the desired uniform bin size. DNL and INL are related. For there to be non-trivial INL, there must be both bins with smaller size than desired and bins with larger size than desired.

Data converters are prone to high values of INL and DNL as a result of component variations. Many A/D converters use comparators, which accept two analog inputs and provide an output signal indicative of which input is larger. However, any given comparator has an input offset voltage which represents a difference between input values at which output transitions occur. The input offset voltage consists of a fixed offset that results from manufacturing variations and a time-varying offset which depends on component aging and, more importantly, on temperature.

Most A/D converters use passive components, particularly resistors and capacitors, for signal processing. For instance, a resistor ladder is used to generate a set of reference voltages in flash A/D converters, while residue-based A/D converters often use capacitors to implement arithmetic operations such as addition, subtraction, and multiplication. Inaccuracies in absolute component values or inaccurate ratios of component values lead directly to arithmetic or reference errors, and consequently to non-ideal converter transfer functions.

Still another cause of INL and DNL is mismatch in scaled transistor sizes. For instance, transistors may be used to provide a set of binary-scaled reference currents. For the binary scaling to be precise, the relative transistor sizes must be precise. However, to do this in some IC fabrication technologies, such as CMOS, may require a larger-than-minimum smallest transistor size. This results in a converter which may occupy a large amount of chip space. Similar dimensional expansion may be required for passive component matching as well.

As an alternative to designing overly-large components, be they comparators, resistors, capacitors, or transistors, it may be possible to trim or calibrate component values. Resistors and capacitors can be laser-trimmed at the time of manufacture in many IC manufacturing processes. However, this adds an additional step and costly laser-trimming machinery to the production costs. A recent innovation proposed for CMOS processes, which are well-established and widely used for digital circuits, is self-adaptive silicon (SAS). In a SAS chip, some individual transistor parameters can be modified after fabrication via a floating gate electrode to which electric charge is selectively added or subtracted. A commercially-available digital-to-analog (D/A) converter from Impinj includes SAS-based calibration to 16 bits of precision. A/D converters using SAS technology are likely to offer similar precision.

It is the opinion of the applicant that the present invention offers simple means and methods for generating reference waveform segments which are accurate to between 18 and 20 bits of precision, resulting in immediate performance improvement relative to many existing A/D conversion techniques. Also, it is quite likely that the same simple approaches can obtain accuracies of even greater precision, perhaps aided by low-cost analog circuitry such as multiple filter stages, or by digital processing of multiple measurements to compensate for the physical vagaries of particular implementation technologies.

Conclusion, Ramifications, and Scope

The reader will see that the present invention has several advantages over prior art sinusoidal signal generators, particularly with regard to a number of important applications and implementation technologies.

With the present invention a piece-wise nonlinear reference waveform can generated for use in an A/D converter based on comparison and elapsed time recording. Waveform segments used for comparison have a desired accuracy, while waveform segments not used for comparison are allowed to be inaccurate.

Of particular use are sinusoidal waveform segments. It is quite easy to generate sinusoids that overall are distorted but that in certain segments are accurate. Generation circuits for low-quality sinusoids can use a small number of components that are easy to design and build using standard integrated circuit fabrication processes such as CMOS technologies. Allowing some distortion enables easy start-up and maintenance of oscillation without complicated and costly dynamic gain control circuitry. Generation circuits for high-quality sinusoids can be made with a low-quality sinusoid generator followed by a desired number of filtering stages, all of which are simple to design.

A compact, low-cost, robust circuit embodying the present invention can be implemented in mixed-signal CMOS technologies to great advantage. For instance, the invention can be included as part of a CMOS image sensor array chip. One non-linear segment waveform generated by the invention can be shared among multiple converters operating simultaneously on different sensor outputs. Additionally, the cost of high-precision conversion using the invention is only moderately greater than that of low-precision conversion—assurance of suitable accuracy for the sinusoidal reference waveform segments and a digital counter of suitable precision and speed. It is possible to increase from today's standards of 8 or 12 bits per image sensor to 16 bits or more, resulting in a greatly increased dynamic range for still or video imaging.

The description above contains many specific details relating to data conversion techniques, precision, speed, cost, conversion times, frequencies, component values, circuit design, sample-and-hold circuits, track-and-hold circuits, multiplexing circuits, comparators, counters, piece-wise linear analog reference waveforms, piece-wise non-linear analog reference waveforms, non-linear segment waveforms, linear segment waveforms, parameter estimation, error correction, component sharing, and applications. These should not be construed as limiting the scope of the present invention, but as illustrating some of the presently preferred embodiments of the present invention. The scope of the invention should be determined by the appended claims and their legal equivalents, rather than by the examples given.

I claim:

1. A machine comprising an oscillator for producing a non-linear segment waveform for use in a conversion application from the set of conversion applications consisting of analog-to-digital conversion and digital-to-analog conversion, said non-linear segment waveform having the following properties:
a. said non-linear segment waveform consists of comparison-useful segments and comparison-irrelevant segments
b. said comparison-useful segments are substantially equal to segments of desired non-linear waveform shapes
c. said comparison-useful segments are, in said conversion application, waveform segments which are not treated as linear waveform segments
d. said comparison-irrelevant segments comprise a non-zero portion of said non-linear segment waveform
whereby said oscillator may produce a waveform which includes some segments of desired, accurately-known non-linear waveform shape and which also includes some segments of unknown or undesired waveform shape, the former segments, for instance, sinusoidal segments, being suitable for processing in said conversion application with accurate knowledge of their non-linear waveform shape taken into account, the latter segments, for instance, unchanging or insufficiently well-known time-varying segments, being tolerated but not used for comparison, so that the waveform may have high distortion globally, but low distortion locally.

2. The machine of claim 1 in which said non-linear segment waveform is periodic, whereby said comparison-useful segments occur repeatedly over time, whereby said comparison-irrelevant segments have a non-zero duty cycle, and whereby said non-linear segment waveform can be generated using low-cost oscillatory generation means.

3. The machine of claim 1 in which:
a. said oscillator is fabricated on a first integrated circuit chip
b. non-oscillator conversion circuitry is also fabricated on said first integrated circuit chip
whereby said oscillator and other conversion circuitry of said conversion application, for instance, comparators, counters, or digital registers, are fabricated on the same integrated circuit chip, resulting in manufacturing cost savings, operating cost savings, or both.

4. The machine of claim 3 further including a sensor fabricated on said first integrated circuit chip, whereby said oscillator, said non-oscillation conversion circuitry, and said sensor can be fabricated on the same integrated circuit chip, such as may be desired in an imaging sensor array that is part of a digital imaging system.

5. The machine of claim 3 further including a transducer fabricated on said first integrated circuit chip, whereby said oscillator, said non-oscillation conversion circuitry, and said transducer can be fabricated on the same integrated circuit chip, such as may be desired in an transducer array that is part of an image display system.

6. The machine of claim 1 in which said conversion application is analog-to-digital conversion, said machine further including:
a. a first comparator having a first comparator input, a second comparator input, and a first comparator output
b. means for providing said non-linear segment waveform as an input to said first comparator input during a first conversion cycle
whereby said non-linear segment waveform can be used as a reference analog signal level compared by said first comparator to a signal applied to said second comparator input during said first conversion cycle, with a change in said first comparator output indicating when the difference between the comparator inputs reaches zero during said first conversion cycle.

7. The machine of claim 6 further including:
a. a second comparator having a third comparator input, a fourth comparator input, and a second comparator output
b. means for providing said non-linear segment waveform as an input to said third comparator input during said first conversion cycle
whereby said non-linear segment waveform can be used as a reference analog signal level for both said first comparator and said second comparator during said first conversion cycle, so that said non-linear segment waveform can be shared in parallel analog-to-digital converters.

8. The machine of claim 1 in which said conversion application is digital-to-analog conversion, said machine further including:
a. a first analog hold-capable circuit such as a track-and-hold circuit or a sample-and-hold circuit
b. means for causing said first analog hold-capable circuit to hold a first value of said non-linear segment waveform reached during a first conversion cycle
whereby said non-linear segment waveform can be used as a reference analog signal level the value of which is tracked and then held or sampled and then held during said first conversion cycle.

9. The machine of claim 8 further including:
a. a second analog hold-capable circuit
b. means for causing said second analog hold-capable circuit to hold a second value of said non-linear segment waveform reached during said first conversion cycle
whereby said non-linear segment waveform can be used as a reference analog signal which is shared by both said first analog hold-capable circuit and said second analog hold-capable circuit during said first conversion cycle, so that said non-linear segment waveform can be shared in parallel digital-to-analog converters.

10. The machine of claim 1 in which said non-linear segment waveform is a truncated sinusoid, whereby saturated peaks and valleys of said truncated sinusoid may be comparison-useless segments, while transitions between said saturated peaks and valleys of said truncated sinusoid may be comparison-useful segments.

11. The machine of claim 1 in which said oscillator comprises:
a. an operational amplifier having an inverting input, a non-inverting input, and an output
b. a positive feedback network connecting said output and said non-inverting input, said positive feedback network providing a positive feedback gain between said non-inverting input and said output which is frequency-dependent
c. a negative feedback network connecting said output and said inverting input
whereby an op-amp circuit using a Wien Bridge can be the means for generating said non-linear segment waveform.

12. The machine of claim 11 in which the negative feedback gain of said negative feedback network connecting said output and said inverting input is greater than the maximum positive feedback gain, whereby said output is forced to saturate.

13. The machine of claim 11 in which said positive feedback network comprises:
a. a first positive network leg connected between said output and said non-inverting input
b. a second positive network leg connected between said non-inverting input and a reference node
whereby a simple bridge circuit can set said positive feedback gain.

14. The machine of claim 13 in which said reference node is ground.

15. The machine of claim 13 in which said reference node is not ground.

16. The machine of claim 13 in which:
a. said first positive network leg comprises a first resistor in series with a first capacitor, said first resistor having a first resistance value and said first capacitor having a first capacitance value
b. said second positive network leg comprises a second resistor in parallel with a second capacitor, said second resistor having said first resistance value and said second capacitor having said first capacitance value
whereby said positive feedback network is substantially a Wien Bridge, which requires only one capacitance value and one resistance value, and for which a resonant frequency of maximum positive feedback gain is easily computed or designed for by proper choice of component values.

17. The machine of claim 16 in which said negative feedback network comprises a third resistor connected between said output and said inverting input and a fourth resistor connected between said inverting input and either said reference node or a second reference node having substantially the same voltage as said reference node, whereby said negative feedback network is implemented with a simple resistor bridge.

18. The machine of claim 17 in which said third resistor and said fourth resistor have values such that the negative feedback gain is greater than three, whereby said negative feedback gain is greater than said positive feedback gain.

19. The machine of claim 13 further including a second operational amplifier configured to force said non-inverting input to be a virtual ground.

20. The machine of claim 19 in which said reference node is the output of said second operational amplifier.

21. The machine of claim 20 in which the output of said second operational amplifier is connected to one end of a leg of said negative feedback network, the other end of which is connected to said inverting input, whereby said second operational amplifier provides a common reference node for both said negative feedback network and said positive feedback network.

22. A machine for producing a sinusoidal reference waveform, comprising:
a. a first oscillatory waveform which is a truncated sinusoid at a first fundamental frequency
b. as said sinusoidal reference waveform, a second oscillatory waveform which is a filtered version of said first oscillatory waveform, said second oscillatory waveform substantially having less relative attenuation at said first fundamental frequency than at other frequencies, in comparison with relative attenuation at said first fundamental frequency and at other frequencies in said first oscillatory waveform
whereby said first oscillatory waveform is a truncated, and hence high-distortion sinusoid at said first fundamental frequency, and whereby said second oscillatory waveform is also a sinusoid at said first fundamental frequency but with lower distortion due to a higher relative gain (or equivalently a lower relative attenuation) at said first fundamental frequency than at other frequencies, a low-distortion sinusoid being produced by filtering a high-distortion sinusoid being particularly useful in integrated circuit implementations where an oscillator must be built using a small part count of components selected from a small library of standard components such as capacitors, resistors, and transistors.

23. The machine of claim 22 comprising:
a. a first operational amplifier having a first inverting input, a first non-inverting input, and a first output
b. a positive feedback network connecting said first output and said first non-inverting input, said positive feedback network providing a positive feedback gain between said first non-inverting input and said first output, said positive feedback gain being frequency-dependent relatively high at said first fundamental frequency
c. a negative feedback network connecting said first output and said first inverting input, said negative feedback network providing a negative feedback gain which is greater than said positive feedback gain
whereby an op-amp circuit using frequency-dependent positive feedback can be the means for generating said first oscillatory waveform.

24. The machine of claim 23 in which said positive feedback network comprises:
a. a first positive network leg connected between said first output and said first non-inverting input
b. a second positive network leg connected between said first non-inverting input and a reference node
whereby a simple bridge circuit can set said positive feedback gain.

25. The machine of claim 24 in which said reference node is a constant-voltage reference node such as ground.

26. The machine of claim 25 in which said second oscillatory waveform is the value of the voltage at said first non-inverting input.

27. The machine of claim 25 further including means for filtering the value of the voltage at said first non-inverting input to provide said second oscillatory waveform.

28. The machine of claim 24 in which said reference node is not a constant-voltage reference node.

29. The machine of claim 28 in which the value of the voltage at said reference node defines said second oscillatory waveform.

30. The machine of claim 28 further including means for filtering the value of the voltage at said reference node to provide said sinusoidal reference waveform.

31. The machine of claim 24 in which said negative feedback network comprises a third resistor connected between said output and said inverting input and a fourth resistor connected between said inverting input and either said reference node or a second reference node having substantially the same voltage as said reference node, whereby said negative feedback network is implemented with a simple resistor bridge.

32. The machine of claim 24 in which:
a. said first positive network leg comprises a first resistor in series with a first capacitor, said first resistor having a first resistance value and said first capacitor having a first capacitance value
b. said second positive network leg comprises a second resistor in parallel with a second capacitor, said second resistor having said first resistance value and said second capacitor having said first capacitance value
whereby said positive feedback network is substantially a Wien Bridge, which has a single resonant frequency of maximum positive feedback gain, and which requires only one capacitance value and one resistance value, and for which a resonant frequency of maximum positive feedback gain is easily computed or designed for by proper choice of component values.

33. The machine of claim 32 which said negative feedback network comprises a third resistor connected between said first output and said first inverting input and a fourth resistor connected between said first inverting input and either said reference node or a second reference node having substantially the same voltage as said reference node, whereby said negative feedback network is implemented with a simple resistor bridge.

34. The machine of claim 33 in which said third resistor and said fourth resistor have values such that the negative feedback gain is greater than three, whereby said negative feedback gain is greater than said positive feedback gain.

35. The machine of claim 34 further including a second operational amplifier configured to force said non-inverting input to be a virtual ground.

36. The machine of claim 35 in which a second output which is the output of said second operational amplifier is said reference node.

37. The machine of claim 36 in which the output of said second operational amplifier is connected to one end of a leg of said negative feedback network, the other end of which is connected to said inverting input, whereby said second operational amplifier provides a common reference node for both said negative feedback network and said positive feedback network.

38. The machine of claim 36 further including means for filtering the value of said output of said second operational amplifier in order to produce said second oscillatory waveform, whereby one or more filter stages can be used to guarantee suitably low distortion for said sinusoidal reference waveform.

39. The machine of claim 38 in which said means for filtering said value of said output of said second operational amplifier comprises:
a. a third operational amplifier having a third inverting input, a third non-inverting input, and a third output
b. a first filter network leg consisting of a fifth resistor in series with a third capacitor, where:
i. one end said first filter network leg is connected to said second output of said second operational amplifier
ii. the other end of said first filter network leg is connected to said third inverting input
iii. said fifth resistor has substantially the same resistance as said first resistor
iv. said third capacitor has substantially the same capacitance as said first capacitor
c. a second filter network leg consisting of a sixth resistor in parallel with a fourth capacitor, where:
i. one end said second filter network leg is connected to said third inverting input
ii. the other end of said second filter network leg is connected to said third inverting input
iii. said sixth resistor has substantially the same resistance as said first resistor
iv. said fourth capacitor has substantially the same capacitance as said first capacitor
d. said third non-inverting input being connected to ground whereby a second Wien bridge provides means for filtering said second output, with bridge components being substantially similar to the components of the Wien bridge which provides positive feedback for said first operational amplifier.

40. The machine of claim 22 further including means for changing said first fundamental frequency, whereby said machine can be used to generate sinusoidal reference waveforms of more than one frequency.

41. The machine of claim 40 in which said means for changing said first fundamental frequency comprises a circuit comprising one or more members of the set of variable-parameter components consisting of transistors, variable-capacitance capacitors, variable-resistance resistors, and variable-inductance inductors.

42. The machine of claim 41 in which sad means for changing said first fundamental frequency comprises a self-adaptive silicon circuit.

43. The machine of claim 22 further including means for providing said sinusoidal reference signal to a device under test, whereby said sinusoidal reference signal can be used for calibration of said device under test, possible devices including waveform generators, audio equipment, synthesizers, analog-to-digital converters, and digital-to-analog converters.

44. The machine of claim 22 in which:
a. said machine is fabricated on a first integrated circuit chip
b. non-oscillator circuitry is also fabricated on said first integrated circuit chip
whereby rather than having an oscillator chip and a non-oscillator chip, said machine of claim 22 and non-oscillator circuitry are fabricated on the same integrated circuit chip, resulting in manufacturing cost savings, operating cost savings, or both.

45. The machine of claim 44 further including a sensor fabricated on said first integrated circuit chip, whereby said machine of claim 22, said non-oscillator circuitry, and said sensor can be fabricated on the same integrated circuit chip, such as may be desired in an imaging sensor array that is part of a digital imaging system, for instance a CMOS image sensor array.

46. The machine of claim 44 further including a transducer fabricated on said first integrated circuit chip, whereby said machine of claim 22, said non-oscillator circuitry, and said transducer can be fabricated on the same integrated circuit chip, such as may be desired in an transducer array that is part of an image display system.
